(19) United States
(12) Patent Application Publication
(10) Pub. No.: US 2026/0030407 A1
(43) Pub. Date: Jan. 29, 2026

(54) METHOD AND DEVICE FOR USING A DATA MODEL TO MONITOR AND ASSESS A BELT CONVEYOR

(71) Applicant: Innomotics GmbH, 90441 Nürnberg (DE)

(72) Inventors: TORSTEN HELLMUTH, Erlangen (DE); PETER MÄCHLER, Meissen (DE)

(73) Assignee: Innomotics GmbH, 90441 Nürnberg (DE)

(21) Appl. No.: 18/996,290

(22) PCT Filed: Jul. 18, 2023
(86) PCT No.: PCT/EP2023/069910

§ 371 Date: Jan. 17, 2025

(30) Foreign Application Priority Data
Jul. 18, 2022 (EP) 22185499.5

(51) Int. Cl. G06F 30/20

(52) U.S. Cl. CPC G06F 30/20

(57) ABSTRACT

A data model is used in a method for analyzing a belt conveyor, wherein the data model relates to a digital image of the belt conveyor. A first function value of the belt conveyor is determined, and the first function value and a second function value which relates to the belt conveyor or to a further belt conveyor are used to analyze the belt conveyor. The first and second function values are determined spaced apart in time, or the first and second function values relate to different belt conveyors. With the aforedescribed standardization, a benchmark for assessing the performance of a belt conveyor can be established, and the performance of belt conveyors performing a similar transport task can be assessed as well.

The invention relates to a method and an apparatus for using a data model to monitor and assess a belt conveyor and/or a large number of beit conveyors. Both the monitoring and the assessing of the belt conveyor or the large number of belt conveyors relates to the analysis thereof. The present invention relates, moreover, to a computer program product for carrying out the method. The invention relates, in particular, to a method for performance assessment (I.e. the assessment of a performance) of a belt conveyor or a large number of belt conveyors in the mining industry, i.e in mining, with the aid of a digital twin. The digital twin is an example of a data model or an example of the use of a data model.

The method and the apparatus for using a data model to monitor and assess at least one belt conveyor relates, in particular, to condition monitoring and/or a condition prediction for the at least one belt conveyor. The condition monitoring, also called Condition Monitoring (CM), serves, in particular, the purpose of observing the “health condition” of components, machines, assets, plant components and/or plant and by analyzing CM-based data, making statements on changes in this condition. For this purpose, for example Industrial-Internet-Of-Things platforms: IloT platforms for short, are used in order to capture data transmitted by devices, to store it decentrally, to visualize raw data, to analyze data, and/or to visualize results of the analysis. Local solutions are also possible.

The continuous condition monitoring and analysis of parameters of a belt conveyor helps to predict, for example, possible damage, and thus ideally to not let it occur in the first place. This relates, in particular, to important parameters such as vibration or power consumption). In the case of a belt conveyor, sensors can record measured values (for example cooling temperature, vibration, electrical voltage and current of a power converter and/or a motor and/or a torque) at different locations in the plant and to forward them to an evaluation unit, such as the respective Condition-Monitoring-System (CMS) and/or a controller. The CMS can also be integrated in the controller. At least some of the measured data can be processed by the evaluation unit. This can include, for instance, monitoring functions, such as trend indicators, prognoses as well as the recording of raw data.

The data model can also be referred to as a “digital twin”. The digital twin is, in particular, a representation of a real system in a digital context (IT system), for example with the possibility of “setting” the time (that is to say to observe the system quickly or slowly from the past via the present and into the future). The data model can relate to individual systems, part systems as well as complete systems.

Belt conveyors are used, in particular, as a transportation means in the field of the basic materials industry, in ports, in power stations, in mines, etc. Belt conveyors are arguably the most frequently used transportation means in the raw materials industry (mining+cement) in order to efficiently transport bulk material (for example ore, coal, gravel, cement) from one site to another site. Cost pressure, requirements to increase capacity and operation optimization demands are fundamental drivers or requirements for the operation or the user of belt conveyors or other industrial plant.

There are solutions for capturing and assessing technical aspects of a belt conveyor, such as capturing component temperatures and determining trends, in order, for example, to identify wear to components or to ascertain probabilities of failure. In conjunction with data from the operating process, such as delivery rate and operating time, KPIs (KPI: Key performance Index) may be determined with which statements about plant performance can also be obtained.

Requirements relating to industrial plant, as are used or are present, in particular, in the field of mining and cement, can be divided, for example, into two groups. These two groups can also be referred to as types of main groups.

One group includes, for example, at least one of the following machine-engineering aspects: increasing the service life of the components, preventing outages, reducing wear, etc.

A second group includes, for example, at least one of the following process-engineering aspects: preventing downtimes, reducing plant runtime without material transport (no empty trips), fast startup, etc.

Different solutions for monitoring and/or assessing the condition of individual components can be used for the first group, such as the recording of temperatures or vibrations, in particular of different components, such as bearings of transport rollers, bearings of motors, electrical motors, etc. Straightforward boundary value monitoring, for example, takes place thereby in order to prevent immediate damage or to ascertain trends by way of corresponding analysis of this measurement data in order, for example, to obtain statements about the wear or findings about the probability of failure of the individual component.

For example, data from an operating process of the industrial plant, such as delivery rate, energy consumption, operating time, can be used for the second group therefore in order to obtain KPIs for assessing plant performance. KPIs can be defined, for example, by a manufacturer, an operator or a user of the industrial plant according to their own judgment. However, it can consequently be more difficult to compare different plant belonging, in particular, to different operators.

The comparability of belt conveyors can be difficult for the following reasons, for example. Belt conveyors can differ due to one or more of the following aspect(s): topology (in particular based on the topology of the site of installation), conveying capacity, components, etc. In addition, there is a further large number of influencing factors and complex correlations which can be incorporated in monitoring or assessing of the plant.

It is an object of the invention to analyze a belt conveyor more effectively

One solution to the object can be found with a method according to claim 1 or with a belt conveyor according to claim 14, or with a computer program product according to claim 16. Embodiments are found, in particular, according to claims 2 to 13 and 15.

A data model is used in or with a method for analyzing a belt conveyor. The data model is a digital replica of the belt conveyor or relates to it. It is possible to digitally replicate the belt conveyor completely or partially using the digital replica, which can also be referred to as a digital twin. It is therefore a replica of a real belt conveyor, with the belt conveyor being, for example, in a commissioning phase, an operating phase, an idle phase, a repair phase (etc.) or being inoperative or dismantled, but having been operating in the past. With the method, a first function value of the belt conveyor is ascertained. The first function value is ascertained, in particular, with the aid of the data model. This produces a first function value which is standardized. Standardized function values may therefore be formed with the aid of the data model. The data model is embodied, in particular, specifically for a particular belt conveyor. Standardized function values may be formed using this specific data model. The standardization thus makes it possible to compare different belt conveyors. The first function value and a second function value are used for analyzing the belt conveyor. The function values, which are used for analyzing, are, in particular, standardized function values. Function values are therefore standardized with the aid of the data model. There is therefore, for example, a first function value which is standardized and a second function value which is standardized. The two standardized function values can still be called a first function value in the second function value. There are therefore non-standardized function values and standardized function values. The first standardized function value is ascertained, for example, with the aid of a first data model for a first belt conveyor. The second standardized function value is ascertained, for example, with the aid of a second data model for a second belt conveyor. The second function value is therefore ascertained, in particular, with the aid of the data model or with the aid of a further data model for a further belt conveyor. This produces a standardized second function value. The function values can be analyzed, in particular compared with each other, by way of the standardizations. In particular, the first standardized function value is thus compared with the second standardized function value. The second function value relates, for example, to the belt conveyor (which can also be referred to as the first belt conveyor below) or a further belt conveyor (i.e. a second belt conveyor and/or a third belt conveyor, etc.). If the first function value and the second function value relates to the first belt conveyor, the first function value is thus ascertained, for example, before a reconfiguration of the first belt conveyor and the second function value is ascertained after the reconfiguration of the first belt conveyor. The reconfiguration relates, for example, to a new routing. Thus items of data of the belt conveyor can be compared with each other in standardized form before and after the reconfiguration. In a further example, the loading of the belt conveyor changes, in particular the weight of the loading. The loading, together with the topology, consequently has a great influence, in particular on the energy requirement of the belt conveyor if this energy requirement, as an example of a function value, is also independent of topology and can be standardized in respect of the loading. Thus it is possible, for example, to standardize function values of a belt conveyor with different load and, for example, to compare them. A first function value in the case of a first load can therefore be compared with a second function value in the case of a second load since the function values are standardized. In a further example, there can be a first belt conveyor and a further, second belt conveyor which can be compared with each other. The comparison is an analysis. Thus either the first belt conveyor and/or the second belt conveyor can be analyzed. The further (second) belt conveyor (it is also possible for a large number of belt conveyors to be analyzed), for example, at a different location to the first belt conveyor. For the first belt conveyor, a first function value is ascertained which will be standardized or which is standardized. For the second belt conveyor, a second function value is ascertained which will be standardized or which is standardized. The standardization makes it possible to compare the first function values or the first function value of the first belt conveyor with the second function values or the second function value of the second belt conveyor. The standardization takes place with the aid of the data model. A first data model is used as the digital replica for the first belt conveyor. A second data model is used as the digital replica for the second belt conveyor. Forming a digital replica is the task of the data model. The respective belt conveyor can be analyzed by way of the standardization with the aid of the respective digital replicas. Without the standardization it would not be possible to compare the belt conveyors, in particular owing to their topology dependence.

For analyzing at least one belt conveyor, at least the first function value is standardized with the aid of the data model, with a topology dependence of the function values, in particular, being at least reduced by means of the standardization. The standardization can also eliminate the topology dependence from the function value or from the function values. By way of the standardization by means of the data model or by means of the data models for the different belt conveyors it is thus possible to compare, for example, two belt conveyors with each other or to analyze them, which belt conveyors overcome a different height profile and/or which convey different loads.

For analyzing a first belt conveyor and a second belt conveyor, i.e. in particular for a comparison of the first belt conveyor with a second belt conveyor, for example a first function value of the first belt conveyor is standardized with the aid of the first data model for the first belt conveyor, with a topology dependence of the function values, in particular, being at least reduced by means of the standardization, and a second function value of the second belt conveyor is standardized with the aid of the second data model for the second belt conveyor, with a topology dependence of the function values, in particular, being at least reduced by means of the standardization. The first function value is therefore associated with the first belt conveyor and the second function value is associated with the second belt conveyor, with the function values having been rendered comparable by way of the standardization. Thus, for example, belt conveyors which differ from each other by way of the height profile to be overcome, can be compared with each other in respect of their energy consumption and/or their efficiency since the height profile has been standardized out.

Furthermore, for example the further belt conveyor can be operated simultaneously to the first belt conveyor, as it was also operated in the past, with it being possible, for example, for the further belt conveyor to have been shut down or dismantled. A belt conveyor which has been modified and as a modified belt conveyor represents the first belt conveyor can also be referred to as a further belt conveyor. A belt conveyor which transports a different material and/or a different quantity of material can also be referred to as a further belt conveyor. This relates, in particular, to the same belt conveyor, which is used for different things at different times, i.e. for example transports a different material. The function values are ascertained, in particular, at an interval and/or the function values relate to different belt conveyors. Different belt conveyors are therefore, for example, belt conveyors which are at a different location or are operated in different periods. For example, a belt conveyor following modification of this belt conveyor thus differs from a first condition, so a first belt conveyor and a second belt conveyor can be compared. Examples of intervals when ascertaining the function values are:
every minute,
every hour (in particular for process information), . . .
every month (in particular for a long-term assessment of measures which have been implemented, such as replacing parts, the use of a better bearing, the use of a more powerful motor, the use of a different conveyor belt, etc.)
every year (in particular for reasons as in subitem “every month” and/or, in particular, for ascertainment depending on the season, a temperature, snow, rain, etc.)

The function value can also relate to a value or a large number of values which are ascertained/measured every hour, for example, in order to ascertain curves over time with which trend developments become apparent.

In one embodiment of the method, a first function value is ascertained which relates a required energy to the rendered transport task and allows an assessment (benchmark value) of the belt conveyor. The required energy relates, in particular, to the driving energy of all drives of the belt conveyor for transport of goods to be conveyed or a selection thereof. Since, as a rule, belt conveyors are very different, due to different topologies, distances between axles, lifting heights, it is possible for preferably only the belt conveyor under consideration to be assessed in this way and for changes in the behavior of this belt conveyor to be inferred in the medium term and in the long term from the change in this function value. Otherwise a second belt conveyor should be similar or identical to the first belt conveyor in respect of topologies, distances between axles, lifting height, etc. A change in behavior, which can, if necessary, be established over time in the case of the first belt conveyor, can be caused by wear, effects of temperature, deterioration of the functionality of individual components and/or the like.

The analysis of the belt conveyor relates therefore, in particular to a benchmarking, i.e., for example a benchmarking process for belt conveyors (GF), using measured values of the relevant belt conveyors, or of the relevant belt conveyor, from the ongoing operation of a plant which has a belt conveyor or where a belt conveyor is used. An analysis, such as a comparison, is therefore possible without affecting the operation of the belt conveyors, or of the belt conveyor, due to special measuring facilities or measurement runs.

As stated above, belt conveyors can be very different, with a comparability, in particular only with the aid of the above-described first function value, not being possible, or only being possible in isolated cases. In order to nevertheless enable a benchmarking process, certain conditions, in particular, have to be met, such as at least:
1. For the belt conveyor(s) to be analyzed, a digital replica is necessary in which with the aid of mathematical algorithms the electrical and mechanical behavior of the belt conveyor is reproduced. The mathematical algorithms used are based, in particular, on standards, such as DIN and/or CEMA;
2. The belt conveyor(s) is/are standardized with the aid of the digital replica; disparities in particular are consequently eliminated and thus comparable results are provided. The above-described function value is used for this and, in particular, a standardized function value determined by
the elimination of the lifting capacity and,
the exclusive consideration of the mechanically used energy and/or
the suppression of the dynamic operational procedures;
The elimination of the lifting capacity can remove differences resulting from the topology of the belt conveyor; the consideration of the mechanical energy, which is in particular exclusive, removes the effect of different drive configurations and efficiency influences. The suppression of the dynamic operational procedures (for example starting up and stopping) removes effects resulting from different operating behaviors of the belt conveyor. Dynamic operational procedures are, in particular, procedures in which, due to an acceleration, a change in the speed of the goods, which are to be conveyed or which are being conveyed, occurs.

The standardization can therefore take place in one, two or three ways. The standardization allows identical or similar conditions of different belt conveyors to be compared or assessed. The analysis, such as a benchmarking process, does not need to be a snapshot, rather it can also take place over a longer period (a day, a week . . . ). This can consequently ensure that sufficient measurement data is collated in order to determine the first or second function value, which is standardized; loading classes and/or load classes can also be taken into account in the process, as is already described in the final version.

3. The belt conveyors to be compared are advantageously of identical or similar design, with the proportion of the sum of special and secondary resistances in relation to the total resistance, in particular, being of a similar size. An identical design means, in particular, that the belt conveyor is designed according to the rules known from DIN or CEMA. Resistance proportions of a similar size for special and secondary resistances compared with total resistance could be divided into groups, as stated below:

Group 1→special and secondary resistances <5% of the total resistance
Group 2→special and secondary resistances <10% of the total resistance
Group 3→special and secondary resistances <15% of the total resistance This division is representative. It can be adapted to the belt conveyors used for the analysis. The special and secondary resistances are each determined in the digital replicas of the belt conveyors according to the rules known from standards (for example DIN or CEMA). In the DIN there is, for example in order to demonstrate the significance of an indentation rolling resistance for safe plant dimensioning and the lowest possible investment costs and operating costs at the same time, a representation which shows the sizes of the resistance proportions for relatively long belt conveyors, with a distinction being made between a horizontally-running conveyor and a conveyor with an approximately 5% incline. Reference is made in this connection, for example, to the fact that with the increasing use of energy-optimized conveyor belts, in future the proportion of the indentation rolling resistance in the total motion resistance will reduce accordingly. When the resistance proportions of two relatively long belt conveyors of identical design but different inclines are compared, the following resistances will be differentiated: incline resistances, special resistances, secondary resistances, vibration flexure resistances, beit flexure resistances, idler roll rotation resistances and indentation rolling resistances.

In one embodiment of the method, two and/or all three of the above-described conditions are completely or partially met.

Belt conveyors which meet these conditions, that is to say are in the same group, as described under 3., can be compared with each other.

The determination of the two described function values allows:
a first, also non-standardized, function value to be used in order to assess an individual belt conveyor with regard to its operating behavior, it being possible for the operating behavior to incorporate the electrical and mechanical properties as well as the operating quality; The meaning of operating quality can be:
   how continuously does the belt conveyor operate?
   Are there many operating phases where material is not being transported? and/or
   Are there frequent start and stop procedures?
a first, also non-standardized, function value to be used in order to identify medium- or long-term changes in one and the same belt conveyor in order to ascertain, if necessary, separate causes and initiate countermeasures;
the second function value to be used in order to compare different belt conveyors with each other on the basis of the described functionalities of the first function value, with first and second function values being standardized. For example, it is consequently possible to compare the performance of belt conveyors of different works with each other, for example cement works, ore mines, etc. and to carry out a corresponding benchmark process; positive experiences in works A can be transferred to the operating conditions in works B in evaluation of the benchmark process; the benchmark process can provide the basis for the optimization of the operating behavior of belt conveyors at different sites.

In one embodiment of the method, a standardization is carried out for the purpose of analysis. The standardization relates, in particular, to the function value or a large number of function values. A comparability of belt conveyors can be achieved by way of the standardization. A first belt conveyor is therefore comparable by means of the standardization with a second belt conveyor even if the first belt conveyor differs from the second belt conveyor. A difference is produced, for example, due to a different lifting height and/or a different length of the belt of the belt conveyor and/or a different conveyed material and/or a repair, etc. The described standardization can create a benchmark for assessing the performance of a belt conveyor, as well as for assessing the performance for belt conveyors with a similar transport task.

Plant in the mining industry is dimensioned, in particular, according to technical, physical or mathematical rules, with these rules being defined in belt conveyors, for example in the DIN or the CEMA. This enables, in particular, a standardized standardization of belt conveyors. A digital twin can be developed for different belt conveyors and this is based on the rules cited above and can be validated, for example, with measurement data so that it behaves in exactly the same way as its real twin. This can take place on the basis of the dimensioning data or on the use of first measurements during commissioning or shortly thereafter. In this way it is possible to retain, for example, an original condition of the belt conveyor in the digital twin.

In one embodiment of the method, standardization is carried out to an operating load of the belt conveyor. One example of an operating load is the speed at which the belt conveyor is operated.

In one embodiment of the method, standardization is carried out to a characteristic value of a material, wherein the characteristic value relates, in particular, to the weight and/or the quantity of the material or represents its value. The material is the material conveyed, i.e. transported, by the belt conveyor. The standardization to the material, or to the characteristic value of the material, relates, for example, to the load due to the material and/or the specific density of the material. A different loading of the belt conveyor with material produces load classes. Load classes can also be referred to as loading classes. Load classes can, for example, differ from each other as follows or include the following parameters:
differences in quantity at the same speed
metering rule=conveying capacity (for example in tons/hour)/speed (for example in meters/second)

The standardization in load classes makes it possible to standardize the same belt conveyor such that changes in the function value can be identified. The function value can be determined for each load class, changes in the function value over time then allow conclusions about performance and/or condition of the belt conveyor.

In one embodiment of the method, standardization is carried out to a lifting height. The lifting height is the height which has to be overcome or is overcome by means of the belt conveyor. The lifting height can have a positive or negative value or be zero. It is possible for different height profiles of a terrain to be overcome by means of the belt conveyor, so different individual lifting heights are produced, in particular due to an up and down of the terrain, which result in a combined lifting height. The standardization to the lifting height makes it possible to compare different belt conveyors with each other. The function values are ascertained, in particular, for the respective speed and the respective load case and are standardized to the lifting height. It is thus possible to compare different belt conveyors. It is possible, in particular, to also take into account the conveying capacity since it is indirectly included in the load classes.

In one embodiment of the method, the standardization relates to the first function value of the belt conveyor (i.e. in particular of the first belt conveyor) and the second function value of the further belt conveyor. The method can therefore be applied to a plurality of belt conveyors, with the standardization making it possible to compare the different belt conveyors.

In one embodiment of the method, the belt conveyors do not differ in their length and/or conveying capacity by more than 50%, in particular 25%, with the belt conveyors in particular having similar transport tasks. A similar transport task is, for example, when goods of the same type are being transported, such as iron ore, coal, sand, etc. Specification of a maximum difference facilities the comparability and/or reduces the standardization complexity. Belt conveyors which are to be compared are therefore used, in particular, for similar transport tasks. Similar transport tasks result with the following belt conveyors which differ in the length of the route to be covered:
long-distance conveyor in kilometers (transport function from A to B over one or more kilometer(s))
storage location conveyor at a storage location, in particular in 100s of meters (transport function from A to B) bunker discharge conveyor (material discharge function from bunkers or silos).

In one embodiment of the method, the function value is an energy performance index. The energy performance index can also be referred to as an Energy Performance Indicator (EnPI). The energy performance index is a KPI with which the performance of a belt conveyor can be described. However, since belt conveyors differ to a great extent and there is a large number of influencing factors and complex correlations which affect this characteristic number, i.e. the EnPI, it is . . . barely possible to compare different belt conveyors if no standardization is carried out. The standardization produces the comparability of belt conveyors. This means, for example, that an operator of the belt conveyor can ascertain an EnPI and can then also estimate whether the ascertained value is good or poor since a benchmark is available. It is therefore possible to ascertain an energy performance index of a belt conveyor in which, in particular due to the use of a digital twin in connection with real measurement data of the belt conveyor, a benchmark is ascertained which, in particular, allows the operator to immediately assess the performance of his belt conveyor.

If, for example, a digital twin is operated with measurement data from the real plant operation of the belt conveyor (for example delivery rate, speed, operating time) KPIs like the EnPI, inter alia, can be determined. These performance indicators then describe the theoretical performance of the belt conveyor without taking into account changes from the original condition (i.e. for example from the condition shortly after the first start-up). Effects of wear, temperature, summer or winter operation, alignment condition of the belt conveyor (in the case of portable belt conveyors) or other changes are not taken into consideration. The real EnPI can be ascertained, in particular, on the basis of measured values and be compared with the theoretical EnPI. The comparison then allows an immediate assessment of the performance of the plant being considered, i.e. of the belt conveyor.

In one embodiment of the method, a technical deviation and/or a technical malfunction is identified.

Examples of technical deviations are:
a changed power requirement of the drives
an increased resistance to rolling of the belt
etc.
   Examples of technical malfunctions are:
an unplanned downtime and/or an interruption due to damage to components . . .
an unplanned downtime and/or an interruption due to material spillages, belt misalignment, etc.
etc.

In one embodiment of the method, a procedural deviation and/or malfunction is identified. If suchlike is identified, countermeasures can be proposed or automatically implemented.

Examples of procedural deviations are:
the supply of material fluctuates
the supply of material is interrupted, in particular frequently
the belt is running with only partial load
poor energy performance since a higher drive power is nevertheless consumed for less material
a change in the operating behavior due to changes in temperature (for example due to a low temperature; this results in more viscous lubricant and consequently in an increase in the bearing resistance)

Examples of procedural malfunctions are:
frequent interruptions which impair the performance of the belt conveyor,
frequent slowing down of the transportation, which also impairs the performance of the belt conveyor.

Causes of variations and/or deviations can also lie in the plant control. For example, incorrectly set boundary values result in frequent malfunctions and thus in interruptions.

The ascertained function values, and the trend to be derived therefrom, gives an indication of the performance and thus of the condition of the belt conveyor. Items of information for an individual belt conveyor may be derived herefrom in that the function values are determined by means of standardization of the speed and assignment to the described load classes. This standardization allows the function values to be compared in identical operating conditions. The further standardization to the lifting height also allows “similar” belt conveyors to be compared with each other (similar belt conveyors are, for example, those which were designed according to the same standard, transport the same goods, etc.). A performance comparison (benchmarking) among belt conveyors is thus possible. As described above, the function value provides an indication of the condition of the belt conveyor, in particular further investigations are then necessary for a specific ascertainment of the cause (technology or process).

In one embodiment of the method, an intervention in the operation of the belt conveyor is carried out. In particular, a real, i.e. physically present, belt conveyor is meant. The intervention can positively influence the performance, i.e. the efficiency of the belt conveyor. The intervention relates, for example, to a change in the mechanics of the belt conveyor and/or the electrics of the belt conveyor and/or the load of the belt conveyor, etc.

In one embodiment of the method, the effectiveness of the intervention is analyzed. This analysis makes it possible to improve the performance of the belt conveyor incrementally. For example, the second function value and or a further function value is used for analyzing the effectiveness of the intervention. These function values are ascertained or standardized according to the described method.

In one embodiment of the method, an operator of plant in the mining industry, i.e. in particular the operator of a belt conveyor, can assess the performance of the plant being considered, or its development in relation to the original condition. Changes to the plant and the effects thereof (for example new conveyor belt, idler roller replacement, change to start and stop times, transmission replacement) can be assessed quickly. The effects of measures that have been implemented (for example . . . new components in the plant, new operating mode) can be seen quickly. This method can assist the operator in improving the performance of their plant, or in consciously following its development. The belt conveyor is dimensioned, for example, by considering a continuous utilization with nominal load and, if necessary, considering extreme cases. Use of the digital twin allows the current operating situation, for example load situation, belt speed, to also be incorporated in the assessment. Consequently, the results of a “What if?” consideration are more realistic. Therefore, how would the originally dimensioned belt conveyor behave under the current load and speed conditions. With a digital twin of appropriate quality, if necessary, the influences of wear behavior or effects of temperature could be taken into account. The provision of technical data, for example for a maintainer of a plant, is a further aspect of the use of the digital replica, i.e. in particular of a digital twin. This supporting benefit can be strengthened further by linking technical and financial data. Digital solutions of this kind constitute an improvement in the operation of plant in connection with the automation of plant in bulk material handling.

A belt conveyor has, in particular, sensors for ascertaining sensor data, it being possible to use at least one item of sensor data for ascertaining a function value, it being possible to carry out one of the described methods to analyze the function value. For example, a memory-programmable controller, a control system or a monitoring system can be used for analysis.

In one embodiment of the belt conveyor, it has a monitoring system. The monitoring system also offers, for example, the possibility of providing trend analyses. The ascertainment and/or analysis of the function values requires, in particular, data which can be provided by means of a monitoring system or corresponding sensors. The method for ascertainment and/or analysis of the function value can be an integral part of the monitoring system sein or can also be installed separately.

A computer program product is provided for installation on a computing unit, wherein the computer program product is embodied for carrying out one of the described methods.

The invention will be described and explained below on the basis of figures. The individual features of the embodiments shown in the figures may be combined by experts to form new embodiments without departing from the scope of the invention. Identical reference signs designate identical elements. In the drawings:

FIG. 1 shows a method for analyzing a belt conveyor,

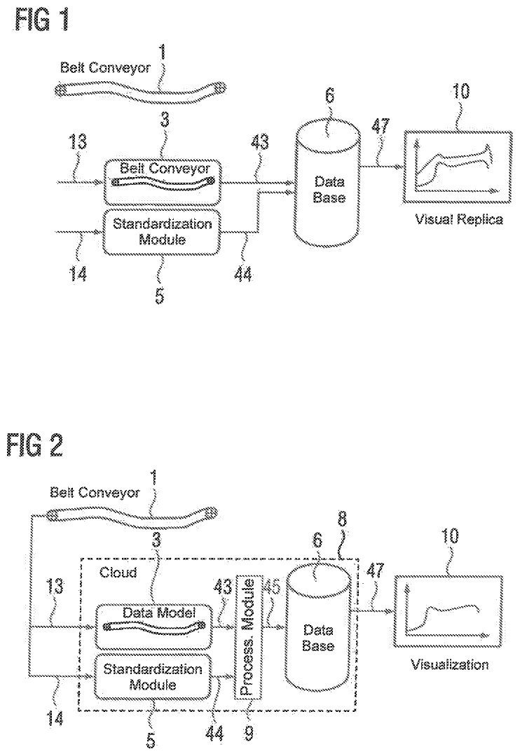

FIG. 2 shows a further method for analyzing a belt conveyor,

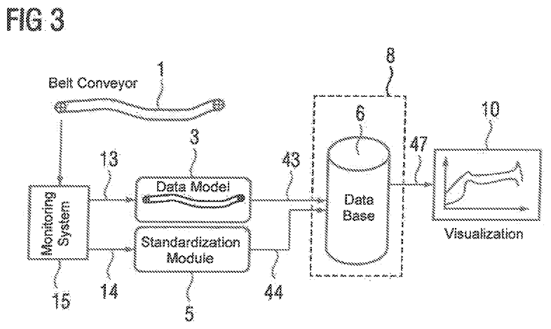

FIG. 3 shows a further method for analyzing a belt conveyor taking into account a monitoring system,

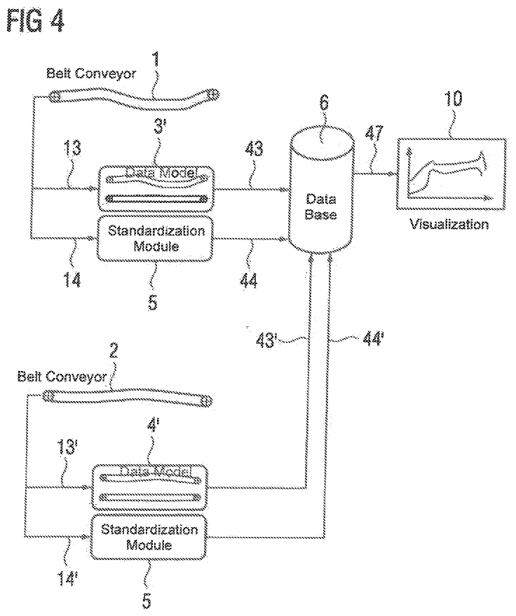

FIG. 4 shows a method for comparing two belt conveyors using one database,

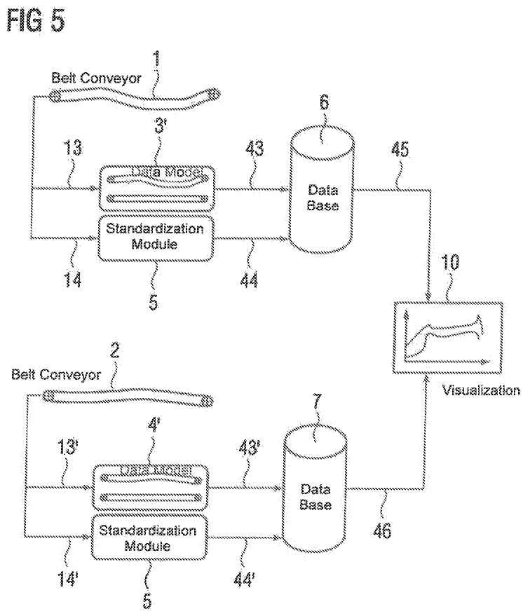

FIG. 5 shows a method for comparing two belt conveyors using two databases,

FIG. 6 shows a first representation of a profile of energy performance indicators,

FIG. 7 shows a further representation of a profile of energy performance indicators,

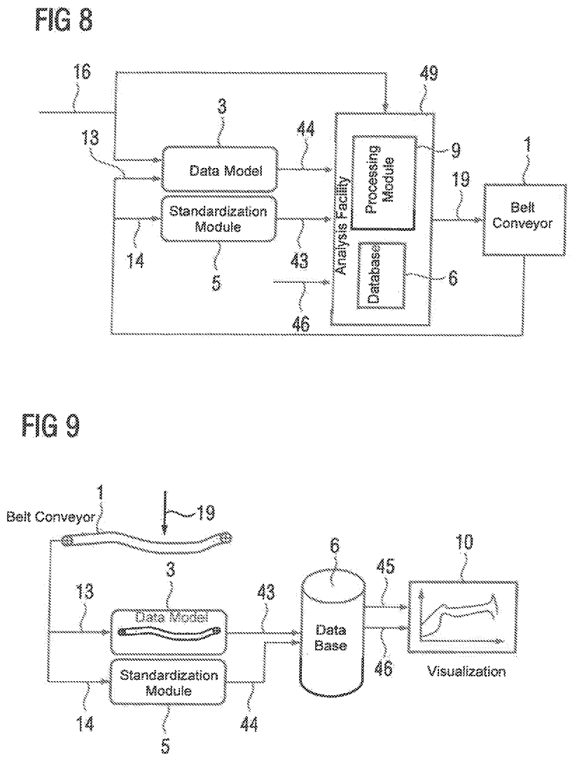

FIG. 8 shows a first representation of an intervention in the operation of the belt conveyor,

FIG. 9 shows a further representation of an intervention in the operation of the belt conveyor,

FIG. 10 shows a sequence of processing steps under specified conditions,

FIG. 11 shows function blocks in simulation software,

FIG. 12 shows drive power and load on the belt over time,

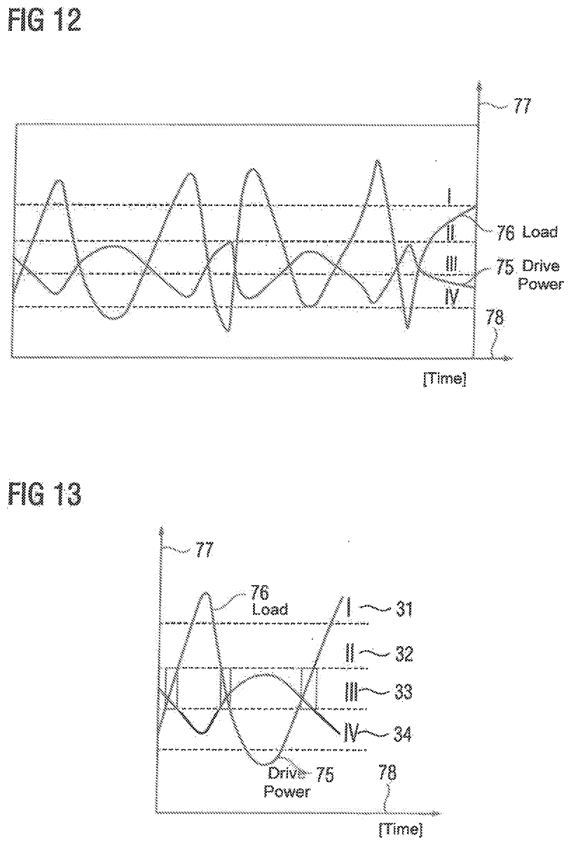

FIG. 13 shows assignments to load classes.

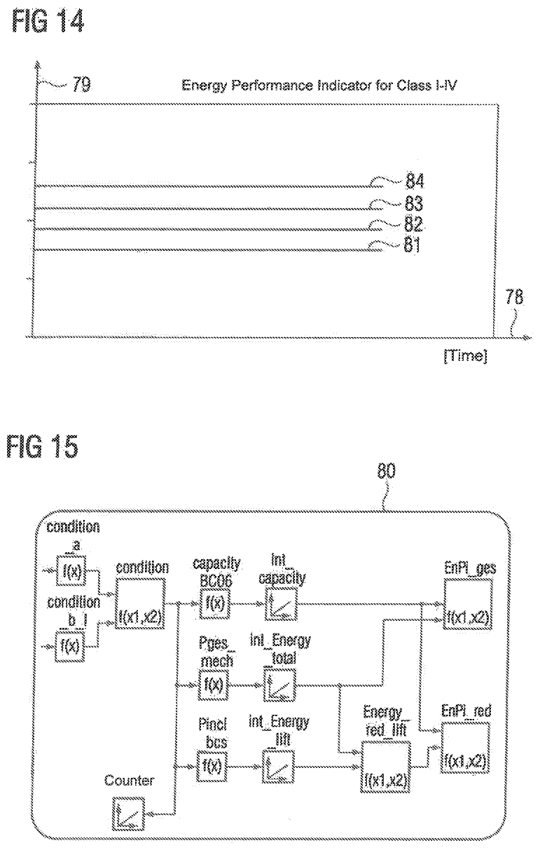

FIG. 14 shows energy performance indicators over time,

FIG. 15 shows a detailed view of an example function block,

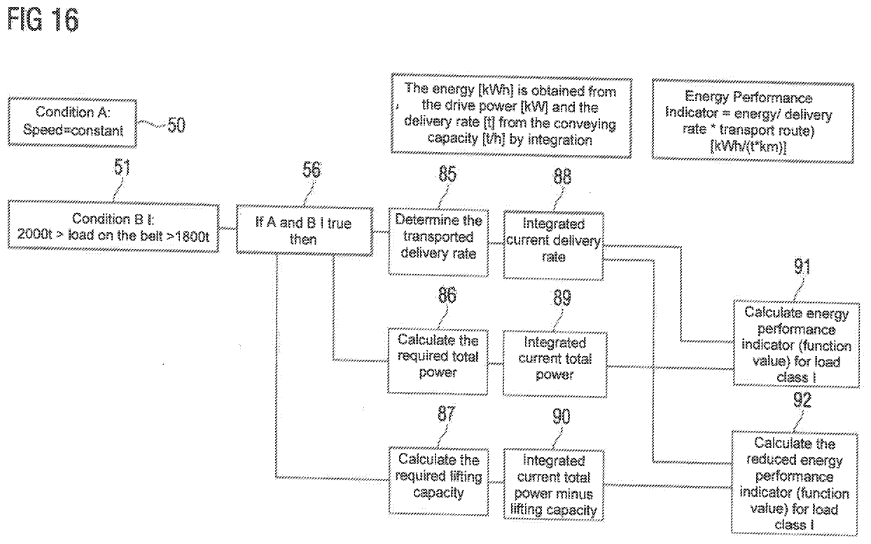

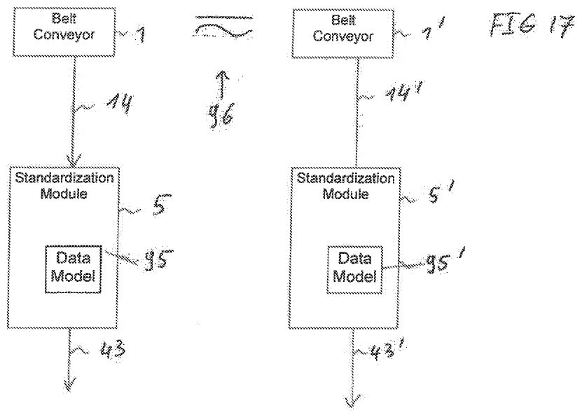

FIG. 16 shows a diagrammatic plan for ascertaining function values, and

FIG. 17 shows standardized and non-standardized first and second function values

The representation according to FIG. 1 shows a method for analyzing a belt conveyor 1. The belt conveyor 1 is a real belt conveyor. A standardized digital replica of the real belt conveyor is produced in or by a data model 3. The digital replica can also be referred to as a digital twin. Measurement data, i.e. real values 13 of the real belt conveyor 1, for, for example, the speed of the belt conveyor and/or the load, i.e. the loading of the belt conveyor, is used in the data model 3. The real values 14 are standardized in a standardization module 5 according to a speed of the . . .

belt conveyor 1 and a load class of the belt conveyor 1. Real values or real measured values 13 are therefore, in particular, the speed and the load for the data model 3. Real values or real measured values 14 for the standardization module 5 are, in particular, a measured power and the load. A result value 43 is ascertained with the data model 3. A result value 44 is ascertained with the standardization module 5. The result values 43 and 44 can already be function values. The result values 43 and 44 are stored in a database 6. First a function value or also a further function value can also be ascertained with the result values 43 and 44. The values are ascertained, for example, in the database 6 or in a further ascertainment facility (not represented). The function values stored in the database can be visualized and/or compared in a visual replica 10. The database 6 provides visualization data 47. The replica therefore provides the possibility of a visualization, an analysis and/or a comparison, in particular of real values with simulated values. Function values are, for example, energy performance indicators. This produces, in particular, a comparison of a development of real measured energy performance indicator with energy performance indicators which are ascertained by way of a simulation by means of the data model 3 with the aid of real measured values 13, 14. The real values: speed and load are the input, i.e. the input variables, for the digital replica, i.e. the data model 3. The required power is calculated and standardized. Use of the load makes it possible to differentiate into load classes. The theoretical energy performance indicators for the respective load class are ascertained according to this standardization in accordance with load classes and speed. The ascertained function values can be plotted against the time in order to map a development or a trend. The digital replica, i.e. the data model, describes, for example, an ideal condition or original condition of the belt conveyor. A standardization similarly has to take place in particular for a comparison with the real belt conveyor.

The consumed energy (in particular a measured value, or calculated from measured values) is standardized, in particular, according to speed and the load classes and the real energy performance indicators determined for the respective . . . load classes. The difference in the results between theoretical and real energy performance indicators describes the plant condition. The analysis or the comparison of at least one real function value with a simulated function value is visualized, in particular by way of a visual depiction 10 by means of a visualization apparatus, like a screen for example.

The representation according to FIG. 2 shows a further method for analyzing a belt conveyor 1, with a first function value 45 being calculated in a processing module 9 from the result values 43 and 44. According to FIG. 2, the data model 3, the standardization module 5 and the database 6 is implemented in a Cloud 8. The Cloud 8 is an internet-based system. Calculations in the Cloud, as well as the storing of data in the Cloud, can take place centrally or decentrally. The visualization 10 of the analysis can take place, for example, on a plant, i.e. in particular where the belt conveyor 1 is also located.

The representation according to FIG. 3 shows a further method for analyzing a real belt conveyor 1, with the real values (measured values) 13 and 14 being taken from a monitoring system 15. The monitoring system 15 monitors the belt conveyor 1. The real values are standardized in the standardization module 5 according to speed and load class. A digital replica of the real belt conveyor is implemented in the data model 3 is, with this being standardized. Here, standardized means standardized according to speed and load class. The database 6 is implemented in the Cloud 8. A comparison can be effected by means of the visual representation 10. Thus, for example, the development of the energy performance indicator, measured for real and in simulated form, can be compared, with real values being used as the input for simulation.

The representation according to FIG. 4 shows a method for comparing two belt conveyors, a first belt conveyor 1 and a second belt conveyor 2, using a shared database 6. According to FIG. 4, compared with the example according to FIG. 1, standardization is also carried out according to the lift in order to be able to compare the different belt conveyors with each other. The data model 3′, which is also standardized according to the lift, and the standardization module 5 is assigned to the belt conveyor. The data model 4′, which is also standardized according to the lift, and a further standardization module 5 is assigned to the belt conveyor 2. The belt conveyor 2 produces the real measured values 13 and 14′. The data models 3′ and 4′ differ from the data models according to FIGS. 1 to 3 by way of an additional standardization according to the lift of the respective belt conveyor 1 or 2. In the symbol for the data model 3, 3′, the belt conveyor is consequently also additionally drawn straight since a standardization exists. The lift is a measure of the inclines (positive as well as negative) which are to be overcome by the belt conveyor. According to FIG. 4, there is therefore also a standardization according to the lift in order to be able to compare, in particular, different belt conveyors with each other which, in particular, have to overcome different height profiles. The standardization thus takes place according to the speed, the load class and the lift. The use of a monitoring system is possible here too, but is not represented. The data models 3′ and 4′ generate result values 43 and 43′. The respective standardization modules 5 generate result values 44 and 44′. Different belt conveyors in a works, a strip mine or a mine can be compared via the data in the database 6.

In contrast to FIG. 4, the representation according to FIG. 5 shows a method for comparing two belt conveyors 1 and 2 using two databases 6 and 7. The database 6 is assigned to the belt conveyor 1. The database 7 is assigned to the belt conveyor 2. A first function value 45 of the database 6 can be compared with a second function value 46 of the database 7. The standardization takes place according to speed, load (load class) and lift. The representation 10 is also possible, for example, by way of a monitoring system which is not represented.

According to FIG. 4 or 5, different belt conveyors in an industrial factory, a strip mine or a mine or also in different works, different strip mines or different mines can therefore be compared. The number of databases 6,7 can be adapted accordingly for this.

The representation according to FIG. 6 shows a comparison 12 of energy performance indicators (EnPI: Energy Performance Indicator) as an example of function values. The following energy performance indicators in the case of a constant speed (for example of 50% or 80% of the nominal speed) and three different load classes I, II and III are represented. The values (data) 21 of the following energy performance indicators are plotted against the time 20 (date), with the values having properties such as: real, theoretical (predicted) and dimensioned (dim (stands for dimensioning, i.e. for an original design of the belt conveyor being considered)):

$$EnPi dim ( load class I ) kWh / ( t * km ) \qquad 22$$

$$EnPi dim ( load class III ) kWh / ( t * km ) \qquad 23$$

$$EnPi theo ( load class II ) kWh / ( t * km ) \qquad 24$$

$$EnPi real ( load class I ) kWh / ( t * km ) \qquad 25$$

$$EnPi real ( load class III ) kWh / ( t * km ) \qquad 26$$

$$EnPi dim ( load class II ) kWh / ( t * km ) \qquad 27$$

$$EnPi theo ( load class I ) kWh / ( t * km ) \qquad 28$$

$$EnPi theo ( load class III ) kWh / ( t * km ) \qquad 29$$

$$EnPi real ( load class II ) kWh / ( t * km ) \qquad 30$$

This is an example of the representation of results of the theoretical and real energy performance indicators over time for three load classes. In accordance with the standardization, these energy performance indicators are standardized according to speed (many belt conveyors operate at a constant speed (fixed speed), fewer at variable speed) and the load classes. The EnPi dim can also be calculated for different load class. This value is a theoretical value based on dimensioning calculations. If the belt conveyor operates at variable speed, the standardization can take place according to the different speeds, load classes and, if necessary, also lift, with this kind of representation of results being, for example, three-dimensional or by means of a matrix, which in not represented in FIG. 6.

The representation according to FIG. 7 shows a further comparison of energy performance indicators as a function of the load classes. The energy performance indicator (for example in kWh/t*km) is represented over the time (for example in minutes (min), hours (h), days (d) or months). The representation differentiates the load classes I (load class I) 31, II (load class II) 32 and Ill (load class III) 33. The energy performance indicators 34, 37 and 40 are based on the original design, that is to say on the dimensioning calculation of the belt conveyor. The energy performance indicators 35, 38 and 41 are theoretical and the energy performance indicators 36, 39 and 42 are real. Theoretical means they were ascertained in the data model, that is to say in the digital twin.

The representation according to FIG. 8 shows the assessment of the effects of an intervention 19 in a real plant, i.e. the belt conveyor 1. The intervention 19 takes place on the basis of an analysis in an analysis facility 49. Function values are analyzed in the analysis facility 49 on the basis of a processing module 9 and a database 6 and an intervention 19 is generated in the belt conveyor. Plant data 16 is also processed in the analysis facility 49. Sensor data 11 produces, for example, the measured values 13 and 14.

The representation according to FIG. 9 shows how an intervention 19 can be analyzed. The described method can be used for assessing interventions that have been implemented. Interventions are changes to the real belt conveyor 1. The effectiveness of an intervention can be assessed by the ascertainment of function values. An intervention is, for example, a lower loading or also a greater loading of the belt conveyor, or a belt replacement.

The representation according to FIG. 10 shows a sequence of processing steps under specified conditions. The following elements are shown:
50 condition A at constant speed (constant speed)
51: condition B I with 2000t>load on the belt 1800t
52: condition B II with 2000t>load on the belt 1800t
53: condition B Ill with 2000t>load on the belt 1800t
54: condition B IV with 2000t>load on the belt 1800t
56 If A and B I true then
57 If A and B II true then
58: If A and B III true then
59: If A and B IV true then
60,61,62,63: Integrated current drive power and conveying element
64: calculation of the energy performance indicator (function value) for load class I
65: calculation of energy performance indicator (function value) for load class II
66: calculation of energy performance indicator (function value) for load class III
67: calculation of energy performance indicator (function value) for load class IV

Integration produces the energy [kWh] from the drive power [KW] and the delivery rate [t] from the conveying capacity [t/h]. The energy performance indicator is calculated from the energy divided by (delivery rate*transport route) [kWh/(t*km)].

The representation according to FIG. 11 shows function blocks 70,71,72 and 73 in simulation software for ascertaining energy performance indicators for four load classes:
I 31,
II 32
III 33
IV 74.

For a belt conveyor, the representation according to FIG. 12 shows the values 77 for the drive power 75 and load 76 on the belt over the time 78 divided into load classes I, II, III and IV. A boundary condition is a constant speed, such as 40%, 100% or 110% of the nominal speed.

The representation according to FIG. 13 shows assignments to load classes. For example, load class III, i.e. the time in which the load 76 is in this class, is considered. This produces the knowledge about the drive power 75 which is consumed in the same time. The conveying capacity pertaining thereto is assigned to class III in order to thus then determine the energy performance indicator. The range being considered in class Ill has a gray background.

The representation according to FIG. 14 shows the approximately parallel profile of the values 79 of energy performance indicators of different classes 1 to IV:
81 EnPL_I
82 EnPI_II
83 EnPI_III
84 EnPI_IV
   over the time 78. This shows a user that nothing significant on the belt conveyor has changed in this period.

The representation according to FIG. 15 shows a detailed view of an example function block 80. One function block is provided for each load class. The standardization according to the lift is considered, that is to say, in particular a reduction by the lifting work. In addition to the representation of the function blocks in FIG. 11, the further standardization according to the lift is also represented here.

The representation according to FIG. 16 shows a diagrammatic plan for ascertaining function values for a load class, and, more precisely, once as a total value and once reduced by the lifting capacity, that is to say, standardized to the lifting height (lift=0m).

The following elements are shown:
50: condition A at constant speed (constant speed)
51: condition B I with 2000t>load on the belt 1800t
56: If A and B I true then
85: ascertainment of the transported delivery rate
86: calculation of the required total power
87: calculation of the required lifting capacity
88: integrated current delivery rate
89: integrated current total power
90: integrated current total power minus lifting capacity
91: calculation of the energy performance indicator (function value) for load class I
92: calculation of the reduced energy performance indicator (function value) for load class I.

Integration produces the energy [kWh] from the drive power [KW] and the delivery rate [t] from the conveying capacity [t/h]. The energy performance indicator is calculated from the energy divided by (delivery rate*transport route) [kWh/(t*km)].

The representation according to FIG. 17 shows standardized and non-standardized first and second function values. Symbolically represented is a first belt conveyor 1 and a second belt conveyor 1′. Real first measured values 14 of the first belt conveyor 1 are fed into the first standardization module 5, with the first standardization module 5 having a first data model 95 for simulation of the first belt conveyor 1. A first result value 43 is ascertained with the first standardization module 5. The first result value 43 can simultaneously be the first function value, with this first function value being standardized by the first standardization module 5. Real second measured values 14′ of the second belt conveyor 1′ are fed into the second standardization module 5′, with the second standardization module 5′ having a second data model 95′ for simulation of the second belt conveyor 1′. A second result value 43′ is ascertained with the second standardization module 5′. The second result value 43′ can simultaneously be the second function value, with this second function value being standardized by the second standardization module 5′. The standardized function values 43, 43′ can be compared with each other. The comparison by way of the standardization works since the belt conveyors 1, 1′ are comparable, and this is symbolized by the symbol=96.

1.-16. (canceled)

17. A method for analyzing a belt conveyor, the method comprising:
establishing a data model relating to a digital replica of the belt conveyor;
ascertaining a first function value of the belt conveyor;
ascertaining a second function value of the belt conveyor or of a further belt conveyor;
standardizing with the aid of the data model at least the first function value and at least reducing by means of the standardization a topology dependence of the function values; and
analyzing the belt conveyor with the first function value and the second function value.

18. The method of claim 17, wherein the first function value and the second function value relate to one belt conveyor or to a plurality of belt conveyors having an identical design or similar designs.

19. The method of claim 18, wherein the first function value and the second function value are determined at different times or wherein the first function value and the second function value are associated with different belt conveyors.

20. The method of claim 17, wherein standardization is carried out with respect to an operating condition.

21. The method of claim 17, wherein standardization is carried out with respect to a characteristic value of a material.

22. The method of claim 21, wherein the characteristic value relates to a weight or a quantity of the material.

23. The method of claim 17, wherein standardization is carried out with respect to a lifting height.

24. The method of the claim 17, wherein the standardization relates to the first function value of the belt conveyor and the second function value of the further belt conveyor.

25. The method of the claim 17, wherein a length or a conveying capacity of the belt conveyor and of the further belt conveyor do not differ by more than 50%.

26. The method of the claim 25, wherein the belt conveyor and the further belt conveyor perform similar transport tasks.

27. The method of the claim 17, wherein the first function value and the second function value is an energy performance index.

28. The method of the claim 17, further comprising identifying a technical deviation or a technical malfunction.

29. The method of claim 17, further comprising identifying a process deviation or a process malfunction.

30. The method of the claim 17, further comprising performing an intervention in the operation of the belt conveyor or the further belt conveyor.

31. The method of the claim 30, further comprising analyzing an effectiveness of the intervention.

32. A belt conveyor comprising:
sensors for ascertaining sensor data to be used for ascertaining a function value, and
a data model of the belt conveyor relating to a digital replica of the belt conveyor,
wherein the function value is analyzed with the method set forth in claim 17.

33. The belt conveyor of claim 32, further comprising a monitoring system.

34. A computer program product stored on a non-volatile computer-readable medium for installation on a computing unit, the computer program product comprising computer program instructions which when read into a memory and carried out by a processor of the computing unit, cause the computing unit to carry out the method set forth in claim 17.
